(19) United States
(12) Patent Application Publication
(10) Pub. No.: US 2016/0159230 A1
(43) Pub. Date: Jun. 9, 2016

(54) VEHICLE-BODY INTEGRATED TYPE SOLAR CELL FOR VEHICLE

(71) Applicant: Hyundai Motor Company, Seoul (KR)

(72) Inventors: Mi Yeon Song, Seoul (KR); Won Jung Kim, Seoul (KR); Moon Jung Eo, Seoul (KR); Hae Yoon Jung, Seoul (KR); Sang Hak Kim, Seoul (KR)

(21) Appl. No.: 14/925,496

(22) Filed: Oct. 28, 2015

(30) Foreign Application Priority Data
Dec. 5, 2014 (KR) 10-2014-0173921

(51) Int. Cl. B60L 11/18; H01L 31/048; H01L 51/44; H01L 31/0224; H01L 31/028; B60L 1/00; H01L 31/18; H01L 31/056; H01L 31/032

(52) U.S. Cl. CPC B60L 11/1816; H01L 31/056; H01L 31/0481; H01L 51/448; H01L 31/0322; H01L 31/028; B60L 1/00; H01L 31/1884; H01L 31/1892; H01L 31/022466

(57) ABSTRACT

The present invention relates to a solar cell for a vehicle which can be integrated with a vehicle-body. The solar cell includes an ultrathin-film solar cell layer formed on a flexible ultrathin-film substrate such that the solar cell can be attached to the vehicle body without creases and the solar cell may be easily applied to the vehicle even without changing design of the vehicle body. Further, electric power controllers are individually connected to the respective solar cells attached to the respective parts of the vehicle, thereby minimizing a loss of energy caused by a difference in operating performance between the solar cells.

### CROSS-REFERENCE TO RELATED APPLICATION

This application claims under 35 U.S.C. §119 a the benefit of Korean Patent Application No. 10-2014-0173921 filed on Dec. 5, 2014, the entire contents of which are incorporated herein by reference.

### TECHNICAL FIELD

The present invention relates to a solar cell that may be integrated with a vehicle body. More particularly, the solar cell may be an ultrathin-film solar cell layer formed on an ultrathin-film substrate having elasticity and thus, the solar cell may be excellently attached to a vehicle body without creases. Accordingly, the solar cell can be manufactured to be integrated with the vehicle body and the solar cell may be easily applied to the vehicle even without changing design of the vehicle body. Further, electric power controllers may be individually connected to the respective solar cells attached to the respective parts of the vehicle, and a loss of energy caused by a difference in operating performance between the solar cells may be minimized.

### BACKGROUND

Recently, in order to solve problems about energy, various researches have been conducted on an alternative energy source that may be substituted for the existing fossil fuel.

In particular, widespread researches have been conducted to utilize natural energy such as wind power or solar energy, and among others, as an alternative energy source, a solar cell using solar energy may be in the limelight because the solar energy is environmentally friendly and an unlimited resource.

Accordingly, researches on a method of mounting the solar cell have also been actively conducted in vehicle industries. For example, hybrid electric vehicles, electric vehicles (EV), or high-grade vehicles, which include a solar cell panel mounted on an upper surface of the vehicle body such as a sunroof, has been actually sold.

In the related arts, Korean Patent Application Laid-Open No. 10-2013-0034996 discloses a technology of installing a silicon solar cell on door glass, rear glass, an upper roof panel, and a trunk panel of the vehicle. However, the method disclosed in the Korean Patent Application Laid-Open No. 10-2013-0034996 has a drawback in that design of a vehicle body needs to be changed into a flat structure so that the silicon solar cell is attached to the vehicle body.

Further, U.S. Patent Application Laid-Open No. 2008-0110485 discloses a solar cell finishing material that is applicable to a surface of a vehicle, however, when a solar cell is manufactured on a steel plate of the vehicle, a short between a (+)-electrode and a (−)-electrode may occur because a surface of the steel plate is rough, and efficiency of the solar cell may deteriorate.

As such, there is an acute need for a research that may ensure high output energy by enlarging an area where the solar cell is applied up to the entirety or most of the vehicle body, and may improve a matching property with the vehicle body.

When the solar cells are connected to one another in the form of a series/parallel array structure and then attached to the respective parts of the vehicle, an angle at which sunlight is received may vary according to a position to which the solar cell is attached, and as a result, difference in performance between the solar cells may be caused even though the solar cells have the same characteristics. Further, due to characteristics of the series/parallel array structure, the solar cell of low performance may be exhibited, and as a result, efficiency of the solar cells may deteriorate.

Accordingly, there is a need for a research on a method which may connect the respective solar cells without deterioration in performance at the time of attaching the solar cells to the respective parts of the vehicle.

The above information disclosed in this Background section is only for enhancement of understanding the background of the invention and therefore it may contain information that does not form the prior art that is already known in this country to a person of ordinary skill in the art.

### SUMMARY OF THE INVENTION

In preferred aspects, the present invention provides a solar cell which can be manufactured to be integrated with a vehicle body so that the solar cell may be securely attached to the vehicle body without changing design of the vehicle body. Further, the solar cell may have reduced weight so that when the solar cell is attached to the entirety or most of the vehicle, the total weight of the vehicle may not be increased substantially. The present invention also provides a solar cell in which the solar cells are individually attached to the respective parts of the vehicle, such that when a damaged vehicle is repaired, the solar cell that is attached to the part to be repaired may be replaced. Moreover, electric power of the solar cell may be individually controlled such that performance of all of the solar cells may not deteriorate due to a difference in performance between the respective solar cells attached to the respective parts of the vehicle.

In one aspect, provided is a solar cell that can be integrated with the vehicle body. The solar cell may include: a substrate; and a solar cell layer formed on a first surface of the substrate. In particular, the substrate may be formed in an ultrathin-film having elasticity and the solar cell layer may be formed in an ultrathin-film. The solar cell may be attached to the entirety or a part of the vehicle for each part of the vehicle without changing or deteriorating design of a vehicle body.

The “ultrathin-film substrate”, as used herein, may have a thickness substantially reduced from the typically used substrate material. For example, a thickness of a ultrathin-film substrate, e.g. polymer or glass substrate, may be preferably less than about 100 μm, less than about 90 μm, less than about 80 μm, less than about 70 μm, less than about 60 μm, less than about 50 μm, less than about 40 μm, less than about 30 μm, less than about 20 μm, less than about 10 μm, less than less than about 5 μm or particularly the thickness thereof may be of about 1 μm to 5 μm.

Further, the “ultrathin-film solar cell layer” may have a thickness substantially reduced from the typically used solar cell layer and formed in a coating or film type. The thickness thereof may be preferably less than about 1 μm, less than about 900 nm, less than about 800 nm, less than about 700 nm, less than about 600 nm, or particularly, less than about 500 nm or particularly the thickness thereof may be of about 100 nm to about 500 nm In particular, the ultrathin-film solar cell layer of the invention may comprise a transparent electrode, an activation layer, and a counter electrode, which can be formed by printing or coating on the ultrathin-film substrate.

In certain preferred aspects, a thickness of the ultrathin-film substrate may be suitably of about 1 μm to about 5 μm. Further, in certain preferred aspects, a thickness of the ultrathin-film solar cell layer may be suitably about 100 nm to about 500 nm

In a preferred embodiment, the ultrathin-film substrate may include a polyethylene terephthalate foil or a polydimethylsiloxane film.

In a preferred embodiment, the ultrathin-film solar cell layer may be any one of an organic solar cell layer, a copper indium gallium selenide (CIGS)-based solar cell layer, or a silicon thin-film-based solar cell layer.

In a preferred embodiment, the solar cell may further include a protecting layer, such as a hard coating layer, which may be disposed on the ultrathin-film solar cell layer and protects the solar cell. In certain preferred embodiments, transmittance of the hard coating layer may be of about 80% to about 100%.

The term “transmittance”, as used herein, may refer to a ratio or fraction of light or radiant energy that enters and transmits through a substance. The transmittance of light may be directed to any wavelength of radiation energy based on the substance that the light passes through, such as UV light, infrared, or visible light. For instance, the “transmittance” of the hard coating layer of the present invention may be measured at the wavelength of the light at which the solar cell layer can produce an electric energy substantially and efficiently. In a further preferred embodiment, the solar cell may further include a reflecting film which may be disposed on a second surface of the ultrathin-film substrate that contacts a steel plate of the vehicle. The reflecting film may be included to reflect light on the second surface.

In a further preferred embodiment, the solar cell that is integrated with the vehicle body may be attached to at least one or more vehicle parts, such as a roof, an engine room hood, a fender, a door, a trunk lid, and a bumper of the vehicle.

In a further preferred embodiment, the respective solar cells may store electric power in a battery without being interrupted by other solar cells using electric power controllers that are individually connected to the solar cells.

Further provided are vehicles that comprise the solar cell as described herein. Particularly, the vehicles may comprise the solar cell as being integrated to the body of the vehicles, and more particularly, the solar cell may be connected at least one or more parts of the vehicle.

In another aspect, the present invention provides a method of manufacturing a solar cell for a vehicle. The method may comprise: fixing an ultrathin-film substrate to a flexible substrate supporter; and forming a solar cell layer on the ultrathin-film substrate.

The flexible substrate supporter may be a polyethylene terephthalate (PET) suitably having a thickness of about 100 μm (0.1 mm) or greater.

The solar cell layer may be formed by printing or depositing a transparent electrode, an activation layer, and a counter electrode onto the ultrathin-film substrate using the roll-to-roll process.

The method may further comprise applying an adhesive onto a steel plate or a vehicle body, and attaching the solar cell to the steel plate. In addition, the method may further include removing the flexible substrate prior to attaching the solar cell to the steel plate.

Other aspects and preferred embodiments of the invention are discussed infra.

### BRIEF DESCRIPTION OF THE DRAWINGS

The above and other features of the present invention will now be described in detail with reference to certain exemplary embodiments thereof illustrated in the accompanying drawings which are given hereinbelow by way of illustration only, and thus are not limitative of the present invention, and wherein:

FIG. 1 is an exemplary cross-sectional view illustrating an exemplary solar cell for a vehicle according to an exemplary embodiment of the present invention;

FIG. 2 shows an exemplary first process of manufacturing the solar cell for of FIG. 1; FIG. 3 shows an exemplary second process of manufacturing the solar cell of FIG. 1;

FIG. 4 is an exemplary cross-sectional view illustrating an exemplary solar cell for a vehicle according to an exemplary exemplary embodiment of the present invention;

FIG. 5 is an exemplary cross-sectional view illustrating an exemplary solar cell for a vehicle according to an exemplary embodiment of the present invention; and

FIG. 6 is an exemplary method of connecting an electric power controller of a vehicle according to an exemplary embodiment of the present invention.

Reference numerals set forth in the Drawings include reference to the following elements as further discussed below:

10: ultrathin-film substrate

20: ultrathin-film solar cell layer

21: transparent electrode

22: activation layer

23: counter electrode

30: hard coating layer

40: reflecting film

50: flexible substrate supporter

60: electric power controller

It should be understood that the appended drawings are not necessarily to scale, presenting a somewhat simplified representation of various preferred features illustrative of the basic principles of the invention. The specific design features of the present invention as disclosed herein, including, for example, specific dimensions, orientations, locations, and shapes will be determined in part by the particular intended application and use environment.

In the figures, reference numbers refer to the same or equivalent parts of the present invention throughout the several figures of the drawing.

### DETAILED DESCRIPTION

It is understood that the term “vehicle” or “vehicular” or other similar terms as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles, e.g., fuel derived from resources other than petroleum. As referred to herein, a hybrid vehicle is a vehicle that has two or more sources of power, for example both gasoline-powered and electric-powered vehicles.

The terminology used herein is for the purpose of describing particular exemplary embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about.”

Hereinafter, reference will now be made in detail to various embodiments of the present invention, examples of which are illustrated in the accompanying drawings and described below. While the invention will be described in conjunction with exemplary embodiments, it will be understood that the present description is not intended to limit the invention to those exemplary embodiments. On the contrary, the invention is intended to cover not only the exemplary embodiments, but also various alternatives, modifications, equivalents and other embodiments, which may be included within the spirit and scope of the invention as defined by the appended claims.

Hereinafter, exemplary embodiments of the present invention will be described in detail with reference to the accompanying drawings so that those skilled in the art to which the present invention pertains may easily carry out the exemplary embodiments. However, in the description of the exemplary embodiments of the present invention, the specific descriptions of publicly known functions or configurations will be omitted when it is determined that the specific descriptions may unnecessarily obscure the subject matter of the present invention.

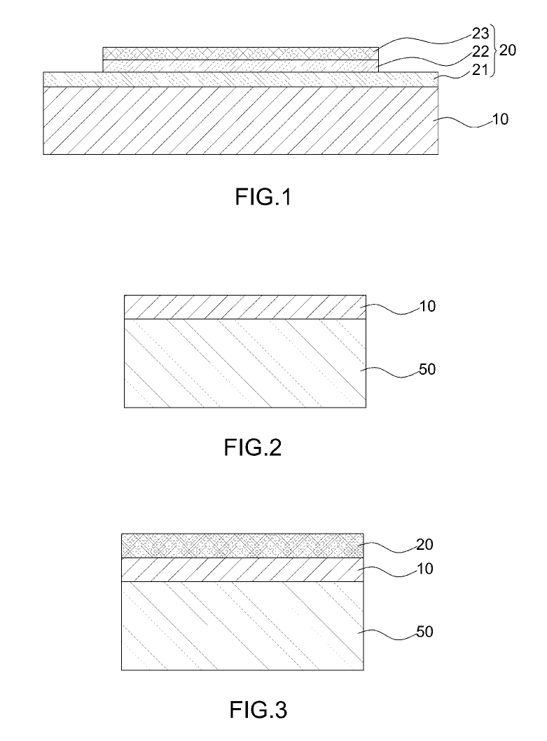

As shown in FIG. 1, a solar cell for a vehicle or a solar cell that is integrated in a vehicle body (hereinafter, both of them may be referred to as ‘solar cell’) may include a substrate 10, and a solar cell layer 20 which is formed on a first surface of the substrate. The substrate 10 may be formed in an ultrathin-film and have elasticity or flexibility.

Since the ultrathin-film substrate 10 has elasticity, the solar cell may be attached to a vehicle without changing a design or a shape of the vehicle body. In contrast, as described above, the conventional solar cell in the related art needs to be mounted on a flat surface on the vehicle.

In particular, the ultrathin-film substrate 10 may have elasticity or flexibility, and as a result, the solar cell may be easily attached to the vehicle body without creases. In other words, the solar cell including the ultrathin-film substrate 10 may be attached or mounted closely to the vehicle body, and as a result, the design of the vehicle body may not be damaged.

The ultrathin-film substrate 10 may be formed of any material or may be formed in any shape, which is typically used in the related arts. In particular embodiments, the ultrathin-film substrate 10 may be made of a polymeric material and formed to suitably have a thickness, less than about 100 μm, less than about 10 μm, or particularly ranging from about 1 μm to about 5 μm. The ultrathin-film substrate 10 may be, but not limited to, a polyethylene terephthalate (PET) foil or a polydimethylsiloxane film

The ultrathin-film solar cell layer 20 may be any type of solar cell layers used for substantially producing electric power in the solar cell of the related arts.

The ultrathin-film solar cell layer 20 may be, but not limited to, an organic solar cell. Further, based on design, color, processes, and the like of the vehicle, any type of solar cell, in particular, an ultrathin-film solar cell such as a thin-film silicon-based solar cell, and a CIGS (copper indium gallium selenide) based solar cell may be used as the ultrathin-film solar cell layer 20.

The ultrathin-film solar cell layer 20 may be formed to suitably have a thickness of about 100 nm to 500 nm.

As shown in FIG. 1, the ultrathin-film solar cell layer 20 may include a transparent electrode 21, a counter electrode 23, and an activation layer 22 which is interposed between the transparent electrode and the counter electrode.

The transparent electrode 21 may be a positive electrode in the solar cell. Particularly, as material of the transparent electrode 21, indium tin oxide (ITO), indium zinc oxide (IZO), fluorine-doped tin oxide (FTO), and the like may be used, but the transparent electrode 21 is not limited thereto.

Further, a buffer layer (not illustrated) including poly (3,4-ethylene dioxylene thiophene) and poly (styrene sulfonic acid) (PEDOT and PSS) may be formed on an upper portion of the transparent electrode 21, thereby improving electrical contact of the transparent electrode 21 in the solar cell.

The counter electrode 23 may be a negative electrode in the solar cell. The counter electrode 23 may be formed by being patterned to an upper portion of the activation layer 22 through printing/deposition processes. For example, the patterning process may use laser or a pattern printing process.

The counter electrode 23 may use a material that is appropriately selected in accordance with an energy level of an active layer in order to ensure performance of the solar cell. For example, gold (Au), silver (Ag), aluminum (Al) metal, carbon nanotube, graphene, and the like may be used, but the counter electrode 23 is not limited thereto.

The activation layer 22 may absorb light and perform photovoltaic conversion when light enters the solar cell. The activation layer 22 may include a poly (3-hexylthiophene) (P3HT) polymer which serves as an electron-donor, and a phenyl C61-butyric acid methyl ester (PCBM) molecule which serves as an electron-acceptor, but is not limited thereto.

A solar cell in the related art, which is mounted onto a sunroof or the like, may not be applied over the entire area of the vehicle because of a heavy weight of the solar cell. A weight of the vehicle is a factor that is directly associated with fuel efficiency or performance of the vehicle, and thus, when the solar cells are attached to the entire area or a large area of the vehicle, it is essential to reduce a weight of the solar cell. To the contrast, exemplary solar cells according to various exemplary embodiments of the present invention may include ultrathin-film substrates and the ultrathin-film solar cell layers, and as a result, the weight of the vehicle may not be greatly increased even though the solar cell is attached to the entire area or a large area of the vehicle.

As described above, since the solar cell according to the present invention may include ultrathin-film components and have a total thickness of about 1.5 μm to about 5.5 μm, the solar cell may not be easily manufactured through a mass production process.

In an exemplary embodiment, an exemplary solar cell according to the present invention may be manufactured by: fixing an ultrathin-film substrate 10 to a flexible substrate supporter 50 as illustrated in FIG. 2; and forming a solar cell layer 20 as illustrated in FIG. 3.

A polyethylene terephthalate (PET) substrate suitably having a thickness of about 100 μm (0.1 mm) or greater may be used as the flexible substrate supporter 50 so that the flexible substrate supporter 50 may be easily handled and suitable to carry out a process for a large-area solar cell such as a roll-to-roll process.

In particular, the solar cell may be manufactured by uniformly spreading the ultrathin-film substrate 10 on the flexible substrate supporter 50 while covering the flexible substrate supporter 50 without creases, and subsequently, printing/depositing the transparent electrode, the activation layer, and the counter electrode onto the ultrathin-film substrate 10 using the roll-to-roll process to form the ultrathin-film solar cell layer 20.

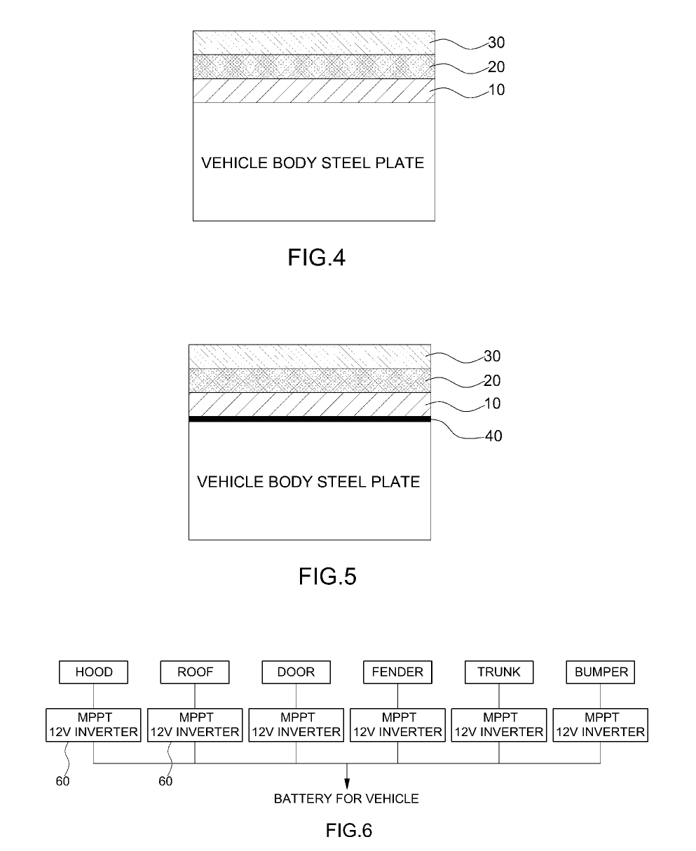

As shown in FIG. 4, the solar cell may be cut corresponding to a portion to which the solar cell is applied, an adhesive may be applied onto a steel plate or a vehicle body, and subsequently, the solar cell may be attached so that the ultrathin-film substrate 10 may be into direct contact with the steel plate. For example, a roller blade or a stamping method may be used so that the solar cell can be properly spread on and attached to the steel plate without creases. In this process, the solar cell may be attached after the flexible substrate is removed.

When a surface of the solar cell is exposed to the outside as illustrated in FIG. 4, the solar cell may be easily damaged by physical impact and easily contaminated. In an exemplary embodiment, an exemplary solar cell may further include a protecting layer. The protecting layer may be a hard coating layer 30 which may be disposed at an upper side of the ultrathin-film solar cell layer 20 and serves as a protective film.

The hard coating layer 30 may satisfy transmittance of at least about 80% so as not to degrade performance of the solar cell. The hard coating layer 30 may be made of, but not limited to, epoxy, polyester, urethane, polyether, polybutadiene, and a silicon acrylate-based UV hardening agent.

Further, the hard coating layer 30 may further include an additional coating layer such as a silver (Ag) coating layer in order to prevent reduction in transmittance when visible light is reflected due to the coating.

As shown in FIG. 5, in an exemplary embodiment, a reflecting film 40 may be applied on the solar cell, particularly when the solar cell is attached or disposed on the vehicle body. When solar cell is additionally coated with the reflecting film, a number of electrons may be generated as much as an amount of light reflected to the active layer, thereby improving performance by at least about 10%.

As described above, the solar cell according to the present invention may be attached to the vehicle for each part of the vehicle. The solar cell may be attached to each part such as a roof, an engine room hood, a fender, a front door, a rear door, a trunk lid, or a bumper of the vehicle.

As described above, the solar cell may be cut corresponding to a shape of each part, an adhesive may be applied onto the steel plate or the vehicle body, and then the solar cell may be spread so that the solar cell may be properly attached to the steel plate without creases.

Since the individual solar cell is attached for each part, for example, if the front door is damaged by a vehicle accident and needs to be replaced, the damaged front door may be replaced with a new front door and merely the solar cell to the replaced front door may be attached. As such, the solar cell of the present invention may be advantageous in terms of maintenance and management.

As shown in FIG. 6, an exemplary solar cell according to an exemplary embodiment of the present invention may store electric power in a battery using electric power controllers 60 which may be connected individually with the solar cells so that the solar cells, which are attached to the respective parts, may not affect by other solar cells or parts.

As described above, in the related arts, when the solar cells are connected in the form of a series/parallel array structure, difference in performance between the solar cells may occur. Further, the solar cell having reduced performance may be exhibited, thereby deteriorating performances or properties of all the other solar cells.

For example, the solar cells, which are attached to the roof, the engine room hood, and the trunk lid, may be placed horizontally, but the solar cells, which are attached to the door, the fender, and the bumper, may be placed vertically, such that the solar cells may receive light at different angle operating performance between the solar cells may be different even though the solar cells are the same in characteristics.

The solar cells, which are attached to the respective parts, may have a difference in area size, such that the solar cells may receive different amounts of sunlight. Further, for example, by virtue of heat that is generated by an engine when the vehicle travels, the solar cell attached to the engine room hood may generate a larger amount of electric power than the solar cells attached to other parts that have the same area as the part of the engine room hood to which the solar cell is attached.

Therefore, in order to maximally and efficiently use electric power generated from the solar cells without a loss of energy, the electric power controllers 60 may be individually connected to the respective solar cells, as illustrated in FIG. 6, so that electric energy produced by each solar cell may be stored in the battery without being affected by the solar cells attached to other parts.

Any device that can control the above described function may be used as the electric power controller 60. For instance, a maximum power point tracker (MPPT) inverter may be used, and the inverter may be positioned at any position in the vehicle.

The present invention may provide the solar cell that may comprise the ultrathin-film solar cell layer formed on the ultrathin-film substrate. In particular, the ultrathin-film substrate may have elasticity and flexibility, such that the solar cell may be attached closely to the vehicle body without creases, such that the solar cell may be easily applied to the vehicle even without changing design of the vehicle body.

According to various exemplary embodiments of the present invention, the substrate and the solar cell layer may be formed as ultrathin films, and thus, the solar cell may suitably have a total thickness of about 1.5 μm to 5.5 μm and weight, such that the weight of the vehicle may not be greatly increased even though the solar cell is attached to the entire area or a large area of the vehicle, thereby improving fuel efficiency and performance of the vehicle.

Moreover, according to various exemplary embodiments of the present invention, the solar cells may be individually and separately attached to the respective parts of the vehicle, such that when the damaged vehicle is repaired, only the solar cell attached to the part to be repaired may be replaced, thereby providing advantageous in maintenance and management.

Further, the electric power controllers may be individually connected to the respective solar cells attached to the respective parts of the vehicle, thereby minimizing a loss of energy caused by a difference in operating performance between the solar cells.

The invention has been described in detail with reference to preferred embodiments thereof. However, it will be appreciated by those skilled in the art that changes may be made in these embodiments without departing from the principles and spirit of the invention, the scope of which is defined in the appended claims and their equivalents.

What is claimed is:

1. A solar cell for a vehicle, comprising:
a substrate; and
a solar cell layer formed on a first surface of the substrate,
wherein the substrate and the solar cell layer are formed in an ultrathin-film.

2. The solar cell of claim 1, wherein a thickness of the substrate of about about 1 μm to about 5 μm.

3. The solar cell of claim 1, wherein the substrate comprises a polyethylene terephthalate foil or a polydimethylsiloxane film.

4. The solar cell of claim 1, wherein the solar cell layer is an organic solar cell layer, a copper indium gallium selenide (CIGS)-based solar cell layer, or a silicon thin-film-based solar cell layer.

5. The solar cell of claim 1, further comprising:
a protecting layer disposed on the ultrathin-film solar cell layer the solar cell.

6. The solar cell of claim 5, wherein the protecting layer is a hard coating layer.

7. The solar cell of claim 6, wherein a transmittance of the hard coating layer is of about 80% to about 100%.

8. The solar cell of claim 1, further comprising:
a reflecting film disposed on a second surface the substrate which contacts a steel plate of a vehicle.

9. The solar cell of claim 1, wherein the solar cell is integrated with a vehicle body.

10. The solar cell of claim 9, wherein the solar cell is attached to at least one or more parts of a roof, an engine room hood, a fender, a door, a trunk lid, and a bumper of the vehicle.

11. The solar cell of claim 9, wherein the solar cell stores electric power in a battery using an electric power controller that is individually connected to the solar cell.

12. A vehicle that comprises a solar cell of claim 1.

13. A method of manufacturing a solar cell for a vehicle, comprising:
fixing an ultrathin-film substrate to a flexible substrate supporter; and
forming a solar cell layer on the ultrathin-film substrate.

14. The method of claim 13, wherein the flexible substrate supporter is formed of a polyethylene terephthalate (PET) having a thickness of about 100 μm or greater.

15. The method of claim 13, wherein the solar cell layer is be formed by printing or depositing a transparent electrode, an activation layer, and a counter electrode onto the ultrathin-film substrate using the roll-to-roll process.

16. The method of claim 13, the method further comprising applying an adhesive onto a steel plate of a vehicle body, and attaching the solar cell to the steel plate.

17. The method of claim 13, the method further comprising removing the flexible substrate supporter prior to attaching the solar cell to the steel plate.

18. The method of claim 13, the method further comprising connecting an electric power controller to the solar cell.
